(19) United States
(12) Patent Application Publication
(10) Pub. No.: US 2026/0005032 A1
(43) Pub. Date: Jan. 1, 2026

(54) AUTOMATED MINIMIZATION OF ETCH VARIATIONS BY ADJUSTING ETCH PROCESS BASED ON PATTERN DENSITY

(71) Applicant: Intel Corporation, Santa Clara, CA (US)

(72) Inventors: Divya Suresh, Portland, OR (US); Egon Sohn, Portland, OR (US); Ajay Sathe, Portland, OR (US); Adane Geremew, Mountain View, CA (US); Yixiong Zheng, Portland, OR (US); Manan Shah, Gilbert, AZ (US); Xian Yao Luo, Chandler, AZ (US); Hale Erten, Hillsboro, OR (US); Bikram Baidya, Portland, OR (US); Vishal Javvaji, Hillsboro, OR (US); Cemil M. Atay, Portland, OR (US)

(73) Assignee: Intel Corporation, Santa Clara, CA (US)

(21) Appl. No.: 18/759,033

(22) Filed: Jun. 28, 2024

(51) Int. Cl. H01L 21/311; H01L 21/02; H01L 21/027; H01L 21/3065

(52) U.S. Cl. CPC H01L 21/31116; H01L 21/02164; H01L 21/0274; H01L 21/3065

(57) ABSTRACT

Techniques, structures, and systems related to etch processing using automated selection of etch parameters are discussed. Patterns of features having differing pattern densities are etched into underlying material layers having the same or similar characteristics such as material composition, thickness, etc. While other process parameters remain substantially constant, gas flows, as defined by a gas flow ratio, of etchant gases are automatically selected from available or selectable gas flow ratios using the pattern densities. The ratio of gas flows increases monotonically with increasing pattern density.

### BACKGROUND

Higher performance, lower cost, increased miniaturization, and greater variety of integrated circuit devices are ongoing goals of the electronics industry. For example, in the production of integrated circuit devices, there is a continuing need to pattern and etch features at a variety of pattern densities. Pattern density plays a pivotal role in shaping etch features within the semiconductor manufacturing process. Even when the incoming stack dimensions remain consistent, variations in the overall pattern density can exert a substantial influence on critical factors like etch rate, uniformity, and selectivity. Given the same etch process, changes in pattern density (between different incoming patterns or across different regions of the same pattern), can cause difficulties. For example, etch processes tuned for higher densities, when used on low density regions, can result in undesirable residues that remain at sidewall trenches due to polymers being trapped in the low density trenches. Conversely, when an etch processes is tuned for lower densities (e.g., by using a more reactive etch), when used on high density regions, over etch is observed. This over etch can cause punch through effects, which in turn can cause shorts between neighboring trenches of the same layer or to underlying trenches.

It is with respect to these and other considerations that the present improvements have been needed. Such improvements may become critical to continually improve integrated circuit device fabrication.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating an example process for fabricating integrated circuit devices using automatically selected etch parameters based on pattern density;

FIG. 2 illustrates a cross-sectional side view of an example integrated circuit device structure having a relatively high pattern density during etch processing;

FIG. 3 illustrates a top-down view of the integrated circuit device structure of FIG. 2;

FIG. 4 illustrates a cross-sectional side view of an example integrated circuit device structure having a relatively low pattern density during etch processing;

FIG. 5 illustrates a top-down view of the integrated circuit device structure of FIG. 4;

FIG. 6 is an illustration of an example system for fabricating integrated circuit devices using automatically selected etch parameters based on pattern density;

FIGS. 7A, 7B, 7C, 7D, and 7E are illustrations of exemplary pattern density to etch parameter mappings;

FIG. 8 is an illustration of an example etch tool for fabricating integrated circuit devices using automatically selected etch parameters based on pattern density;

FIG. 9 is an illustration of an example system network of etch tools for fabricating integrated circuit devices using automatically selected etch parameters based on pattern density;

FIG. 10 illustrates a cross-sectional side view of an example integrated circuit device structure having a relatively high pattern density after etch processing;

FIG. 11 illustrates a cross-sectional side view of an example integrated circuit device structure having a relatively high pattern density after patterned photoresist layer and sacrificial light absorbing material removal;

FIG. 12 illustrates a cross-sectional side view of an example integrated circuit device structure having a relatively high pattern density after formation of metallization structures embedded in a material layer;

FIG. 13 illustrates a cross-sectional side view of an example integrated circuit device structure having a relatively low pattern density after etch processing, patterned photoresist layer and sacrificial light absorbing material removal, and formation of metallization structures embedded in a material layer;

FIG. 14 illustrates a cross-sectional side view of an example integrated circuit device structure having features formed using automatically selected etch process parameters incorporated in an integrated circuit die;

FIG. 15 illustrates exemplary systems employing an integrated circuit assembly including an integrated circuit die having features formed using automatically selected etch process parameters; and

FIG. 16 is a functional block diagram of a computing device, all arranged in accordance with at least some implementations of the present disclosure.

### DETAILED DESCRIPTION

One or more embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized, and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that some embodiments may be practiced without these specific details. In some instances, well-known methods and devices are shown in block diagram form, rather than in detail, to avoid obscuring other aspects of an embodiment. Reference throughout this specification to “an embodiment” or “one embodiment” means that a particular feature, structure, function, or characteristic described in connection with the embodiment is included in at least one embodiment. Thus, the appearances of the phrase “in an embodiment” or “in one embodiment” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

References in the specification to “one implementation”, “an implementation”, “an example implementation”, etc., indicate that the implementation described may include a particular feature, structure, or characteristic, but every embodiment may not necessarily include the particular feature, structure, or characteristic. Moreover, such phrases are not necessarily referring to the same implementation. Further, when a particular feature, structure, or characteristic is described in connection with an embodiment, it is submitted that it is within the knowledge of one skilled in the art to effect such feature, structure, or characteristic in connection with other implementations whether or not explicitly described herein.

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

Techniques, integrated circuit devices, and systems are described herein related to improving etch processing by automatically adjusting etch process parameters based on pattern density.

As discussed, given the same etch process, changes in pattern density can cause difficulties in transferring a pattern from a patterned photoresist layer to an underlying material layer such as a dielectric material layer. For example, variations in pattern density influence etch process factors such as etch rate, uniformity, and selectivity. The discussed pattern density differences may be across different regions of the same pattern being etched into the underlying material layer or they may be between patterns being etched into differing underlying material layers. For example, etch process parameters may be defined for each etch process applied to a workpiece such as partially fabricated wafer, with the selection of the etch process parameters defining the resultant etch. Currently, the inherent variability in pattern density necessitates manual intervention to fine-tune the etch parameters with adjustments to etchant chemistries, temperature settings, and power levels being made to counter potential yield and performance degradation issues.

The techniques discussed herein provide for an automated etch parameter selection process that improves or maintains etch process quality while improving efficiency. For example, the desire to flexibly produce different integrated circuit device products (i.e., with different pattern densities) with similar the same or similar process flows (i.e., etching the differing pattern density patterns into a material layer having the same properties) necessitates etch process parameters for some or all of the etch processes used to produce the product with high quality. Manual intervention can then be come burdensome and a bottle neck for fabrication efficiency. By automatically selecting etch process parameters based on pattern density, etch quality can be maintained or improved while removing the potential bottleneck and streamlining operations. Other advantages will be evident based on the following discussion.

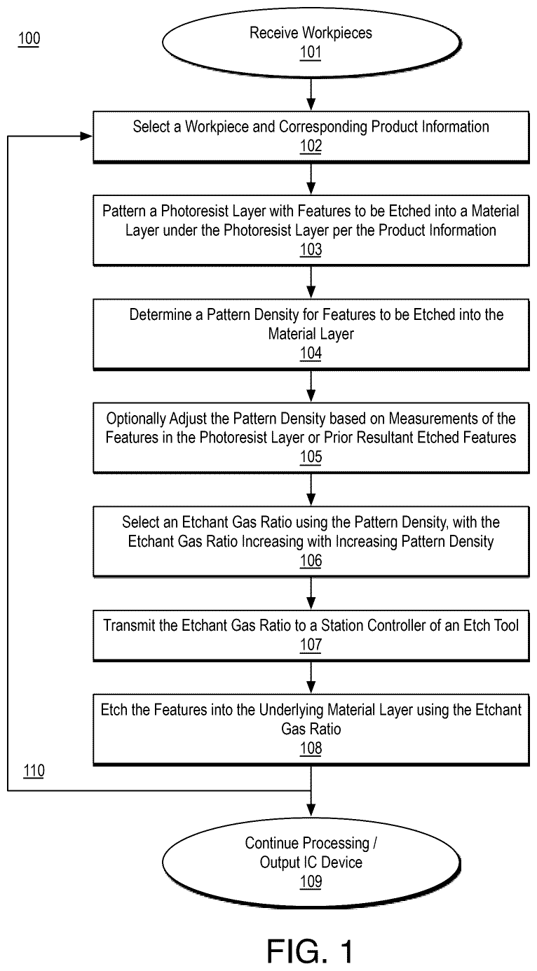

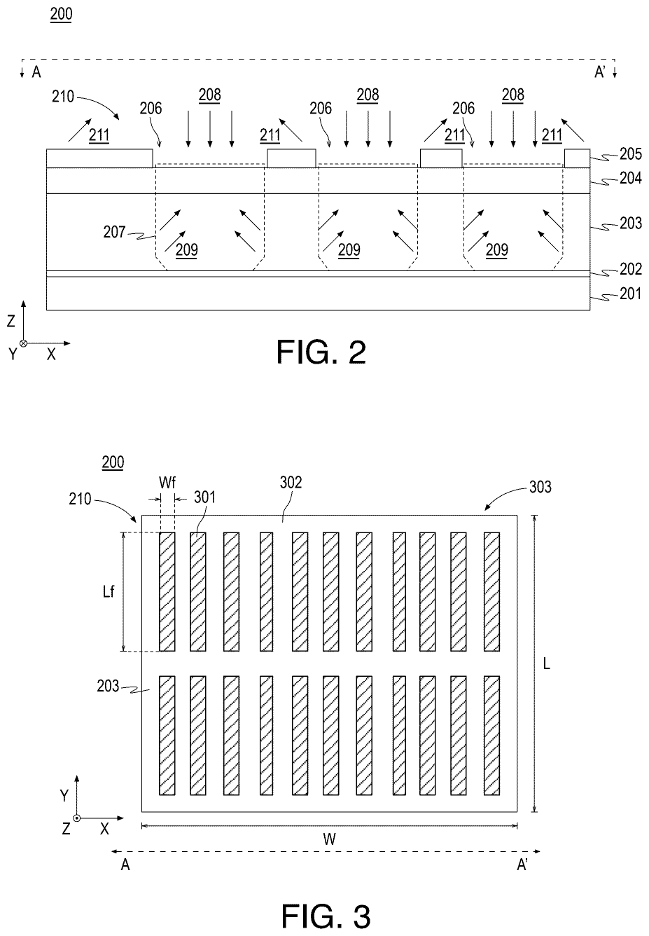

FIG. 1 is a flow diagram illustrating an example process 100 for fabricating integrated circuit devices using automatically selected etch parameters based on pattern density, arranged in accordance with at least some implementations of the present disclosure. For example, process 100 may be implemented to fabricate device structures illustrated in FIGS. 2-5 and 10-14, as discussed herein below.

Process 100 begins at operation 101, where any number of workpieces such as wafers each having a material layer that is to be etched are received for processing. In some embodiments, the material layer is a dielectric layer such as a silicon oxide layer. In some embodiments, the material layer is a carbon doped silicon oxide layer. Although discussed in some contexts with respect to plasma etch of silicon oxide using a carbon-fluorine based gas (such as trifluoromethane) and oxygen, any material layer may be etched using selected gas flow ratios using the techniques discussed herein. In some embodiments, the material layer is a silicon nitride layer, a silicon oxynitride layer, or other material composition.

Notably, each of the separate workpieces (e.g., different wafers or the same wafer at different points in a process flow) has a material layer that has the same or similar characteristics. Such characteristics include material composition, thickness, and others. The pattern to be transferred to each of the separate workpieces, however, differs due to being a different level of the same process flow (e.g., a higher metallization layer) or due to being a different product design, or both. In the context of different levels of the same process flow, the device may be built up in the z-dimension with different build-up layers having differing characteristics such as metallization pattern density while being etched into substantially the same underling dielectric layer. In the context of differing products, the same or similar process flows or layers can be used across product lines with different patterns being called for depending on the product being fabricated.

Therefore, material layers having the same characteristics are to be etched with different pattern densities across wafers or within the same wafer. As used herein, the term pattern density is defined as a ratio of the area of pattern features to total area within a particular region of the surface of the material layer. For example, the pattern density may be A_{PF}/A_{T} where A_{PF} is the area of features to be etched and A_{T} is the total area. Such areas may be determined using any suitable technique or techniques such as being based on the design of the pattern (e.g., an idealized pattern that is designed in a design phase and is part of the reticle information for the pattern), based in part on wafer level measurement at the lithography patterning stage of the current wafer and/or based on final patterning after etch of prior wafers.

As discussed, the material layer to be etched may be over a substrate such as a substrate wafer. The wafer may include any suitable substrate material. For example, the substrate may include a semiconductor material such as monocrystalline silicon (Si), germanium (Ge), silicon germanium (SiGe), a III-V materials based material (e.g., gallium arsenide (GaAs)), a silicon carbide (SiC), a sapphire (Al₂O₃), or any combination thereof. The wafer may further include, in, on, and/or over the substrate, a device layer and one or more metallization layers. The device layer may include transistors, memory devices, capacitors, resistors, optoelectronic devices, switches, or any other active or passive electronic devices, or portions thereof. The metallization layer(s) may include via layers and metal line layers to interconnect and provide access to the devices.

Processing continues at operation 102, where a particular workpiece and corresponding product or process information for the particular layer being processed are selected. As discussed, the material layer being patterned has particular characteristics that may match those of other products or layers being processed, while the pattern to be etched into the material layer is different relative to the other material layers. The product or process information may be any suitable data that selects the pattern to be processed such as a reticle identifier or the like.

Processing continues at operation 103, where the selected workpiece such as a wafer is coated with a photoresist layer, exposed using a lithography tool such as a step and scan exposure tool, and developed to form the selected pattern in the photoresist layer. For example, the selected pattern may be formed as openings in the photoresist layer using known techniques. As shown, the features are in accordance with the product information and have a corresponding pattern density as a ratio of the area of the features to the total area of the workpiece surface within a particular region.

Processing continues at operation 104, where a pattern density for the features being etched into the material layers is determined using any suitable technique or techniques. As discussed, the pattern density is defined as a ratio of the area of pattern features to total area within a particular region of the surface of the material layer. In some embodiments, the total area is an active region of an exposure field that is repeatedly exposed through a reticle and onto the workpiece in the discussed lithography patterning. In some embodiments, the pattern density is A_{PF}/A_{T} where A_{PF} is the area of features to be etched and A_{T} is the total area. For example, the area of the features, A_{PF}, may be a sum of the areas of each of the features patterned into the photoresist layer and then etched into the material layer.

Processing continues at operation 105, where the pattern density is optionally adjusted based on measurements of fabricated features. For example, a design or idealized pattern density may be adjusted based on as fabricated resultant features to fine-tune the pattern density prior to etch parameter selection. In some embodiments, the measured features are openings in the photoresist layer of the current workpiece, as patterned at operation 103. In some embodiments, the measured features are openings in one or more photoresist layers of prior workpieces such that the process parameters match the current process. For example, past measurements for prior workpieces may be used to fine-tune or adjust the pattern density. In some embodiments, the measured features are trenches etched into the underlying material layer for any number of prior workpieces. In some embodiments, the measured features are features such as metal lines formed in the trenches etched into the underlying material layer for any number of prior workpieces. For example, current patterned photoresist dimensions, prior patterned photoresist dimensions, prior patterned material layer dimensions, or prior fabricated feature dimensions for features embedded in the patterned material layer may be used.

As discussed, the area of each feature may be the desired area of the feature (i.e., a feature as designed) or the area of each feature may be a measured area of the feature (or a representative feature corresponding to the feature) as measured in the photoresist pattern, as measured after etch into the material layer, or as measured as a resultant feature embedded in the material layer, or a combination of these. In any case of measurement, a number of representative features may be measured, and the measurements may be used to estimate the feature area (e.g., the measurements may be averaged). In some embodiments, the design or idealized feature arca is adjusted based on the measurements. For example, if the features as measured are found to be 5% smaller than the designed features, the pattern density may be reduced by 5%. In some embodiments, a ratio of measured features to design features (e.g., MF/DF) is determined and the pattern density is adjusted by the ratio (APD=MF/DF*PD), where APD is the adjusted pattern density, MF is the measured size of the features, DF is the design measured size of the features, and PD is the pattern density based on the design. The measured feature sizes may be an average of multiple features at the current workpiece, an average of multiple features at any number of prior workpieces, or a combination thereof.

Processing continues at operation 106, where etch parameters are selected based on the pattern density determined at operation 105. In some embodiments, the etch parameters include an etchant gas ratio of active plasma etch gases. In some embodiments, other etch parameters such as temperature, power levels, pressure, etc. are kept constant and only the discussed etchant gas ratio is adjusted. As used herein the term etchant gas ratio indicates a ratio of a quantity of a first gas to a quantity of a second gas, with both the first gas and the second gas being etchant gases. The quantities may be any suitable quantities of gases such as flow rate (i.e., gas flow), volume, pressure, or the like, with flow rate being preferred in some contexts due to being controllable through standard processing control settings. As shown, the etchant gas ratio increases with increasing pattern density. As discussed further below, the etchant gas ratio may be selected using pattern density by providing ranges of pattern densities and mapping each range to a particular etchant gas ratio, or by applying a function to the etchant gas ratio. In some embodiments, the etchant gas ratio increases monotonically with respect to the increasing pattern density. That is, each increase in pattern density increases etchant gas ratio. However, the increase in etchant gas ratio may not be a proportional (i.e., linear) increase.

In some embodiments, the first etchant gas is a carbon and fluorine based etchant gas (i.e., a gas including molecules that include carbon, hydrogen, and fluorine) and the second etchant gas is oxygen (e.g., a gas including molecules including oxygen). For example, the first etchant gas may be CxHxFx such as CHF₃ and the second etchant gas may be O₂. Such gases may plasma etch dielectric material such as silicon oxide, and others. However, any first and second etchant gases may be deployed using the disclosed techniques. Furthermore, the selected gas ratios may be any ratios that increase the ratio of one gas to another with increasing pattern density. Exemplary gas ratios are discussed further herein below.

Processing continues at operation 107, where the selected etch parameters such as etchant gas ratios are transmitted to an etch tool for use in an etch process. In some embodiments, the etchant gas ratios are determined at a system controller or process controller and transmitted to a tool controller or station controller for use at the etch tool. Systems to determine and transmit etch parameters are discussed further herein below, as are etch tools for implementing the etch parameters.

Processing continues at operation 108, where the selected etch parameters are used to etch features into the underlying material layer using the photoresist layer patterned at operation 103 as a mask. Such etch processing may be performed using any suitable technique or techniques that deploy the etch parameters selected at operation 106 based on the pattern density determined at operation 104 and optionally adjusted at operation 105.

As shown with respect to process loop 110, processing may then continue at operation 102 where operations 102-108 are repeated for any number of selected workpieces, selected products, and so on such that some or all etch layers are processed using etch parameters based on pattern density of the pertinent layer being processed. As discussed, such processing advantageously provides high quality etch results with automatic etch process parameters that provide efficiency due to not needed human intervention. Details of such operations are discussed further herein below.

Furthermore, after individual ones of process loops 110, processing continues at operation 109 where the individual material/etch layer may be further processed to form features such as metallization features, and ultimately each workpiece may be output for additional processing. Such processing may include additional frontside metallization, optional backside metallization, additional backend processing, dicing, packaging, assembly, and so on. The resultant device (e.g., integrated circuit die) may then be implemented in any suitable form factor device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

For example, process 100 provides for determining and/or receiving a first pattern density corresponding to first features to be etched into a first material layer and a second pattern density corresponding to second features to be etched into a second material layer. The first pattern density is greater than the second pattern density. The first material layer and the second material layer have substantially the same characteristics such as material composition, thickness, etc. A first etchant gas ratio is selected based at least in part on the first pattern density and a second etchant gas ratio is selected based at least in part on the second pattern density. The first etchant gas ratio is greater than the second etchant gas ratio in response to the first pattern density being greater than the second pattern density. The first features are etched into the first material layer using the first etchant gas ratio and the second features are etched into the second material layer using the second etchant gas ratio.

In some embodiments, the first and second etchant gas ratios are ratios of a first gas flow rate to a second gas flow rate. In some embodiments, the first gas includes carbon, hydrogen, and fluorine, and the second gas includes oxygen. In some embodiments, the first and second pattern densities are ratios of a features area within a pattern region to a total area of the pattern region. In some embodiments, the first etchant gas ratio is not less than 25% greater than the second etchant gas ratio in response to the first pattern density being not more than 50% greater than the second pattern density. In some embodiments, the first etchant gas ratio is not less than 30% greater than the second etchant gas ratio in response to the first pattern density being not more than 75% greater than the second pattern density. Additional details and options pertaining to these operations are discussed further herein below.

FIG. 2 illustrates a cross-sectional side view of an example integrated circuit device structure 200 having a relatively high pattern density 210 during etch processing, arranged in accordance with at least some implementations of the present disclosure. For example, integrated circuit device structure 200 may be processed using a relatively high etchant gas ratio as discussed herein. FIG. 3 illustrates a top-down view of integrated circuit device structure 200 taken at plane A-A′ as shown in FIG. 2, arranged in accordance with at least some implementations of the present disclosure.

As shown in FIG. 2, integrated circuit device structure 200 includes a material layer 203 over a substrate 201. In the exemplary embodiments, material layer 203 is to be etched to form trenches, and the trenches filled to form a number of line features embedded in material layer 203. However, etch processing may be performed in any suitable process flow context. In some embodiments, via or contact features are formed in material layer 203. In some embodiments, the line, via, or contact features are or include metallization features (e.g., a metal liner and a metal fill within the liner). However, features of any materials such as ferroelectric materials, resistive materials, or the like may be formed within material layer 203 or any other etched material layer discussed herein.

Also as shown, material layer 203 is on an optional etch stop layer 202, and an optional sacrificial light absorbing material 204 is on material layer 203. In some embodiments, one or both of etch stop layer 202 and sacrificial light absorbing material 204 are not deployed. In some embodiments, material layer 203 is a silicon oxide material (e.g., a material including silicon and oxygen). For example, material layer 203 may be an interlayer dielectric material. In some embodiments, etch stop layer 202 is a carbon doped silicon oxide material (e.g., a material including silicon, oxygen, and carbon). In some embodiments, etch stop layer 202 is a silicon nitride material (e.g., a material including silicon and nitrogen). However, etch stop layer 202 may be other materials such as a silicon carbide material (e.g., a material including silicon and carbon). Other materials may be used. Sacrificial light absorbing material 204 may have similar etching properties to that of material layer 203 and may have anti-reflective (e.g., light absorbing) properties that prevent defects during lithographic processing. As discussed, in some embodiments, sacrificial light absorbing material 204 may not be used.

Substrate 201 may include any material(s) such as monocrystalline silicon, germanium, silicon germanium, a III-V materials based material (e.g., gallium arsenide), a silicon carbide, a sapphire, or the like. A device layer of substrate 201, if employed, may include any devices such as transistors, memory devices, capacitors, resistors, optoelectronic devices, switches, or any other active or passive electronic devices. Such devices are fabricated using known techniques such as lithography, etch, deposition, implant, etc.

As discussed with respect to operation 103, a patterned photoresist layer 205 is formed over optional sacrificial light absorbing material 204, material layer 203, and optional etch stop layer 202. Patterned photoresist layer 205 includes any suitable material and has openings 206 therein such that the pattern of openings 206 is to be transferred to material layer 203 using plasma etchant gases 208.

Plasma etchant gases 208 has a ratio of etchant gases selected as discussed with respect to operation 106. In some embodiments, etchant gases 208 include a particular ratio of CxHxFx to O₂. As shown, etchant gases 208 remove portions 207 of optional sacrificial light absorbing material 204 and material layer 203 to expose portions of etch stop layer 202. During such etch processing, byproducts are formed including material layer byproducts 209, which may include SixFx/CxFx/Ox in the context of CxHxFx and O₂ based etch of silicon oxide, and byproducts 211, which may include CxFx in the context of CxHxFx and O₂ based etch. Notably, in relatively high pattern density 210 contexts, reduced photoresist coverage is common (i.e., corresponding to greater pattern density), which increases the formation of byproducts and accelerates etching. This results in a decrease in photoresist selectivity, which, in turn, can lead to issues such as trenching and flaring in the etched features when the ratio of etchant gases is too low. In such contexts, providing a greater ratio of CxHxFx to O₂, which causes greater polymerization, can maintain patterned photoresist layer 205 and aid in quality etch of material layer 203.

Turning to FIG. 3, as shown, portions 207 of material layer 203 within openings 206 are etched to form features 301 within a field region 302. In some embodiments, features 301 are trenches in material layer 203. Eventually, the trenches may be filled with metal or other material that is embedded in material layer 203. Notably, features 301 substantially match openings 206. As discussed, the ratio of etchant gases 208 is advantageously selected based on pattern density 210 of integrated circuit device structure 200. In some embodiments, pattern density 210 is determined as a sum of the area (in the x-y plane) of all of features 301 within selected region 303 divided by the total area of selected region 303 (in the x-y plane). For example, pattern density 210 may be determined as A_{PF}/A_{T} where A_{PF} is the area of features 301 within region 303 and A_{T} is the total area of region 303. With reference to FIG. 3, the total area of region 303 A_{T} may be determined as the length L times the width W of region 303 (e.g., A_{T}=L×W) and the area of features 301 A_{PF} within region 303 may be determined as the sum of length Lf times the width Wf of each feature 301 within region 303 (e.g., A_{PF}=Lf1×Wf1+Lf2×Wf₂+ . . . +LfN×WfN, for N features). In the context of contact or via features 301 and/or non-rectangular regions 303, similar area ratios may be determined based on the pertinent shapes of features 301 and region 303.

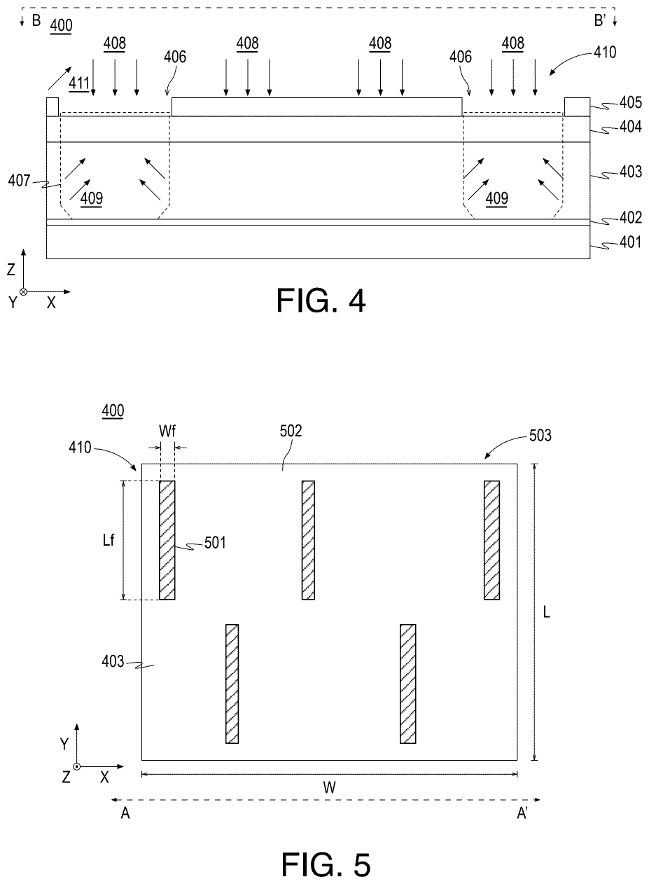

FIG. 4 illustrates a cross-sectional side view of an example integrated circuit device structure 400 having a relatively low pattern density 410 during etch processing, arranged in accordance with at least some implementations of the present disclosure. For example, integrated circuit device structure 400 may be processed using a relative low etchant gas ratio as discussed herein. FIG. 5 illustrates a top-down view of integrated circuit device structure 400 taken at plane B-B′ as shown in FIG. 4, arranged in accordance with at least some implementations of the present disclosure.

As shown in FIG. 4, integrated circuit device structure 400 includes a material layer 403 over a substrate 401. In the exemplary embodiments, material layer 403 is to be etched to form trenches, and the trenches filled to form a number of line features embedded in material layer 403. However, etch processing may be performed in any suitable process flow context. In some embodiments, via or contact features are formed in material layer 403. In some embodiments, the line, via, or contact features are or include metallization features (e.g., a metal liner and a metal fill within the liner). However, features of any materials such as ferroelectrics, resistive materials, or the like may be formed within material layer 403 or any other etched material layer discussed herein.

Also as shown, material layer 403 is on an optional etch stop layer 402, and an optional sacrificial light absorbing material 404 is on material layer 403. Substrate 401, optional etch stop layer 402, material layer 403, and optional sacrificial light absorbing material 404 may have any characteristics discussed with respect to substrate 201, optional etch stop layer 202, material layer 203, and optional sacrificial light absorbing material 204. In particular, such materials may have the same characteristics: compositions, thicknesses, etc. such that the same or similar material stacks are covered with patterned photoresist layers 205, 405 having different pattern densities 210, 410. The characteristics of etch processing and, in particular, the etchant gas ratios of plasma etchant gases 208, 408 are then automatically selected for improved etch processing. In particular, the ratio of CxHxFx to O₂ in plasma etchant gases 408 is less than the ratio of CxHxFx to O₂ in plasma etchant gases 208 such that improved etching is provided in the context of relatively low pattern density 410. That is, in response to relatively high pattern density 210 being greater than relatively low pattern density 410, the ratio of CxHxFx to O₂ in plasma etchant gases 208 is greater than the ratio of CxHxFx to O₂ in plasma etchant gases 408 for improved etching reliability for both of integrated circuit device structure 200 and integrated circuit device structure 400.

As discussed, in some embodiments, one or both of etch stop layer 402 and sacrificial light absorbing material 404 are not deployed. Material layer 403 may be a silicon oxide material and etch stop layer 402 may be a silicon nitride material. However, other material systems may be used. Patterned photoresist layer 405 includes any suitable material and has openings 406 therein such that the pattern of openings 406 is to be transferred to material layer 403 using plasma etchant gases 408. Plasma etchant gases 408 may have any characteristics discussed with respect to plasma etchant gases 208 with differing gas ratios between plasma etchant gases 208, 408.

Plasma etchant gases 408 includes a ratio of etchant gases selected as discussed with respect to operation 106. In some embodiments, etchant gases 408 include a particular ratio of CxHxFx to 02. As shown, etchant gases 408 remove portions 407 of optional sacrificial light absorbing material 404 and material layer 403 to expose portions of etch stop layer 402 while forming byproducts 409, 411 (e.g., SixFx/CxFx/Ox in the context of CxHxFx and O₂ based etch of silicon oxide) and byproducts 211 (e.g., CxFx in the context of CxHxFx and O₂ based etch). Notably, for relatively low pattern density 410, there is typically more extensive photoresist coverage, leading to a reduced presence of oxygen-based byproducts. Instead, carbon and hydrogen fluoride compounds (CxHxFx) may dominate. This difference in byproducts can cause deposition on etched surfaces, which can, in some cases, slow down or even halt the etching process, creating openings or recesses in the features when the ratio of etchant gases is too high. In such contexts, providing a lesser ratio of CxHxFx to O₂ (e.g., more O₂), which causes more aggressive residue removal, can reduce defects for a quality etch of material layer 403. The difference in etch characteristics between relatively high pattern density 210 and relatively low pattern density 410 highlights the importance of understanding and controlling the etch chemistry and conditions for both high and low-density contexts to achieve high quality etch processing. The automatic etch parameter selection discussed herein reduces risk of defects, provides more consistent trench profiles, and improves etch quality across wafer.

Turning to FIG. 5, as shown, portions 407 of material layer 403 within openings 406 are etched to form features 501 within a field region 502. In some embodiments, features 501 are trenches in material layer 403. Eventually, the trenches may be filled with metal or other material that is embedded in material layer 403. Notably, features 501 substantially match openings 406. As with the ratio of etchant gases 208, the ratio of etchant gases 408 is advantageously selected based on pattern density 410 of integrated circuit device structure 400. Pattern density 410 may be determined as a sum of the area (in the x-y plane) of all of features 501 within selected region 503 divided by the total area of selected region 503 (in the x-y plane), as discussed with respect to FIG. 3. For example, pattern density 210 may be determined as A_{PF}/A_{T} where A_{PF} is the area of features 501 within region 503 (e.g., A_{PF}=Lf1×Wf1+Lf2×Wf2+ . . . +LfN×WfN, for N features) and A_{T} is the total area of region 503 (e.g., A_{T}=L×W).

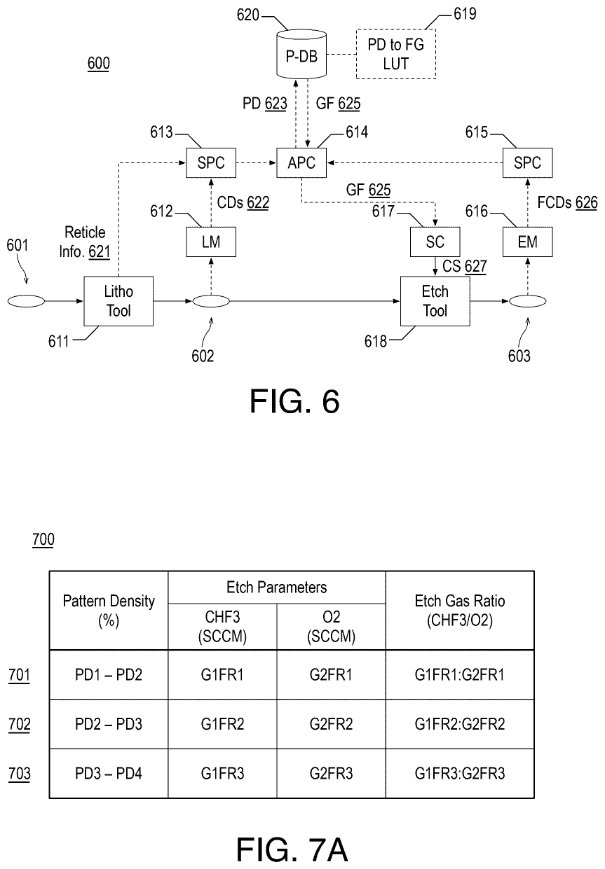

FIG. 6 is an illustration of an example system 600 for fabricating integrated circuit devices using automatically selected etch parameters based on pattern density, arranged in accordance with at least some implementations of the present disclosure. For example, system 600 may implement process 100 and/or other operations discussed herein. As shown, system 600 includes a lithography tool 611 (e.g., a photoresist coat/develop tool coupled to a step and scan tool), a post-lithography measurement tool (LM) 612 (e.g., a scanning electron microscope), a station process controller (SPC) 613 (e.g., a computing device), an advanced process controller (APC) 614 (e.g., a computing device), a process data base (P-DB) 620 (e.g., a memory hub as implemented by a computing device), an etch tool 618 (e.g., a process chamber, control systems, gas supplies, etc.), an etch tool station controller (SC) 617 (e.g., a local computing device to directly control etch tool 618), a post-etch measurement tool (EM) 616 (e.g., a scanning electron microscope), and a station process controller (SPC) 615 (e.g., a computing device). Such components may be implemented as known in the art via tooling, process chambers, support equipment, material supply routing, and so on, under the control of networked computing devices.

As shown, a workpiece 601 such as a wafer having a material layer is received for processing. As discussed with respect to operation 102, workpiece 601 and corresponding product information are selected to etch a particular pattern into the material layer. Workpiece 601 is then processed by lithography tool 611 to form a patterned photoresist layer over the material layer in accordance with the particular pattern to form a patterned workpiece 602. As shown, patterned workpiece 602 is transferred to etch tool 618 for etch using selected etch parameters including an etchant gas ratio as provided by control signal (CS) 627.

Information corresponding to the pattern density of the patterned photoresist layer is part of or may be determined using reticle information 621. For example, reticle information 621 may include the desired pattern to be transferred to the material layer and based on the desired pattern, the pattern density may be determined as the sum of areas of the features (e.g., openings in the photoresist, trench sizes, resultant features sizes, or the like) over the total area of the particular region being evaluated. As shown, reticle information 621 may be transferred to station process controller 613, which may receive or determine the pattern density and transfer it to advanced process controller 614 or transfer reticle information 621 to advanced process controller 614 to determine the pattern density.

In some embodiments, the pattern density is determined only based on reticle information 621. In other contexts, features sizes of openings in the photoresist layer, feature sizes of trenches or other features etched into the material layer, or feature sizes of features formed and embedded in the material layer (not shown) are used to determine or adjust the pattern density as discussed above. For example, features sizes of openings in the photoresist layer may be measured post-lithography and may be characterized as critical dimensions (CDs) 622 as is common in the art. Such critical dimensions 622 are measured at post-lithography measurement tool 612 and transmitted to station process controller 613 and/or advanced process controller 614 to adjust the pattern density as discussed above. Similarly, features sizes of openings in the material layer may be measured post-etch and may be characterized as final critical dimensions (FCDs) 626. Such final critical dimensions 626 are measured at post-etch measurement tool 616 and transmitted to station process controller 615 and/or advanced process controller 614 to adjust the pattern density as discussed above. Notably, such adjustments are based on prior processed workpieces. Feature sizes of features formed and embedded in the material layer may be determined and transmitted to advanced process controller 614 in the same manner.

Advanced process controller 614 may determines a corresponding pattern density (PD) 623 as discussed with respect to operations 104, 105 and retrieves etchant gas ratios or gas flows (GF) 625 for etch of the material layer using, for example, a pattern density to flow gas look up table (PD to FG LUT) 619 as implemented by process data base (P-DB) 620. Although illustrated with respect to pattern density to flow gas look up table 619 other techniques such as applying a function to pattern density 623 to determine etchant gas ratios or gas flows 625 may be used.

Etchant gas ratios or gas flows 625 may include any suitable data structure that includes the information needed by etch tool station controller 617 to control etch tool 618, such as gas flow data, gas pressure data, gas volume data, adjustment data, control data, or the like. Etchant gas ratios or gas flows 625 are received by etch tool station controller 617 and, under control of etch tool station controller 617, etch tool 618 etches patterned workpiece 602 to form etched workpiece 603. Etched workpiece 603 has the pattern etched into the material layer as discussed herein. Etched workpiece 603 may then be measured at post-etch measurement tool 616 to determine final critical dimensions 626 for adjustment of pattern density 623 for future workpieces.

In some embodiments, one or more components of system 600 includes a memory to store a first pattern density corresponding to first features to be etched into a first material layer and a second pattern density corresponding to second features to be etched into a second material layer such that the first pattern density is greater than the second pattern density. The one or more components of system 600 may further include processor circuitry coupled to the memory, the processor circuitry to select a first etchant gas ratio based at least in part on the first pattern density and a second etchant gas ratio based at least in part on the second pattern density. Such storage and selection may be based on a look up table or may be made through other mappings such as application of a function or functions, as is known in the art. The memory and processor circuitry may be housed at the same component of system 600 or they may be housed at the different components of system 600 and communicatively coupled through wired or wireless interfaces. The processor circuitry is further to transmit the resultant etchant gas ratio for use in etch of a workpiece. As discussed, the resultant etchant gas ratio may be transmitted as any suitable data structure. For example, the resultant etchant gas ratio may be explicitly transmitted as a value or the resultant etchant gas ratio may be transmitted using other data (e.g., gas flows, pressures, parameters, etc.) that may implicitly indicate the resultant etchant gas ratio.

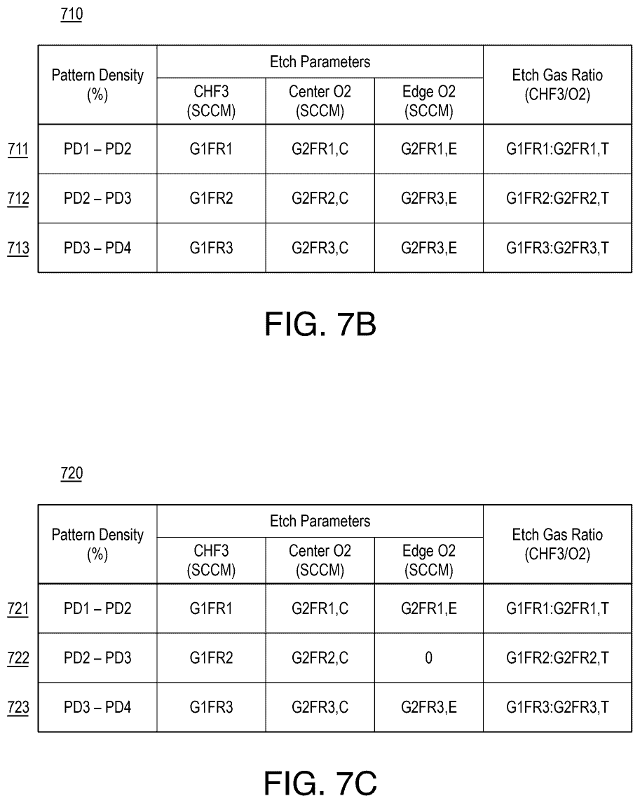

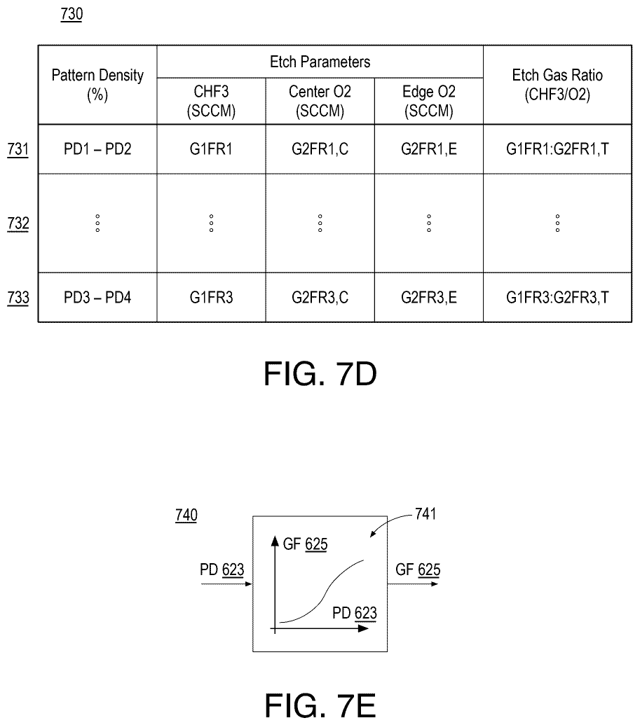

FIGS. 7A, 7B, 7C, 7D, and 7E are illustrations of exemplary pattern density to etch parameter mappings, arranged in accordance with at least some implementations of the present disclosure. Beginning with FIG. 7A, pattern density to etch parameter mapping 700 includes a number of pattern density range to etch parameter mappings 701, 702, 703 such that a received or determined pattern density 623 can be mapped to corresponding etchant gas ratios or gas flows 625. As discussed herein, pattern density is defined as the density of openings in the photoresist layer, the density of trenches or holes in the etched material layer, or the density of features embedded in the material layer, all relative to or divided by the total area of the pertinent region.

In the context of etch parameter mapping 700, three ranges of pattern densities (PD) PD1-PD2, PD2-PD3, PD3-PD4 may be used such that PD4 is greater than PD3, PD3 is greater than PD2, and PD2 is greater than PD1 (PD4>PD3>PD2>PD1). PD1 and PD3 may be smallest and greatest expected pattern densities, however lower limits may not be needed. In some embodiments, PD1 is about 40%, although smaller lower expected pattern densities may be used. In some embodiments, PD2 is about 60%, and PD3 is about 70%. Furthermore, in some embodiments, PD4 is about 80%, although greater expected pattern densities may be used. In some embodiments, the ranges are 40% to 60%, 60% to 70%, and 70% to 80%. In some embodiments, the ranges are 40% to 63%, 63% to 70%, and 70% to 80%. However, other range values may be deployed.

As shown, pattern density range to etch parameter mapping 701 maps the lowest pattern density range (PD1-PD2) to etch parameters inclusive of gas flow rates of, for example, CHF₃ and O₂ and corresponding etch gas ratios (CHF₃/O₂). Although illustrated with respect to CHF₃ and O₂, any gases may be used. In particular any suitable carbon and fluorine based etchant gas (CxHxFx) may replace CHF₃. The gas flow rates of pattern density range to etch parameter mapping 701 includes a first gas flow rate of the first gas G1FR1 and a first gas flow rate of the second gas G2FRI such that the first gas is CHF₃ and the second gas is O₂ corresponding to the lowest pattern density range (PD1-PD2). Furthermore, an etchant gas ratio is defined for pattern density range to etch parameter mapping 701 as G1FR1: G2FR1. In some embodiments, the lowest pattern density range (PD1-PD2) corresponds to a ratio of not more than 6:1 with a first gas flow rate of the first gas G1FR1 of about 120 SCCM (standard cubic centimeter per minute) and a first gas flow rate of the second gas G2FR1 of about 20 SCCM. However, other flow rates may be used. In some embodiments, the lowest pattern density range (PD1-PD2) corresponds to a ratio of not more than 7:1. In some embodiments, the lowest pattern density range (PD1-PD2) corresponds to a ratio in the range of 5:1 to 7:1.

Pattern density range to etch parameter mapping 702 maps the middle pattern density range (PD2-PD3) to etch parameters inclusive of a second gas flow rate of the first gas G1FR2 and a second gas flow rate of the second gas G2FR2, such that the first and second gases are consistent throughout the remainder of FIGS. 7A-7E as discussed with respect to pattern density range to etch parameter mapping 701. Furthermore, an etchant gas ratio is defined for pattern density range to etch parameter mapping 702 as G1FR2: G2FR2. In some embodiments, the middle pattern density range (PD2-PD3) corresponds to a ratio of about 7.5:1 with a second gas flow rate of the first gas G1FR2 of about 120 SCCM and a second gas flow rate of the second gas G2FR2 of about 16 SCCM. However, other flow rates may be used. In some embodiments, the middle pattern density range (PD2-PD3) corresponds to a ratio of not less than 7:1 and not more than 7.8:1. In some embodiments, the lowest pattern density range (PD1-PD2) corresponds to a ratio in the range of 7.1:1 to 7.9:1.

Pattern density range to etch parameter mapping 703 maps the highest pattern density range (PD3-PD4) to etch parameters inclusive of a third gas flow rate of the first gas G1FR3 and a third gas flow rate of the second gas G2FR3. Furthermore, an etchant gas ratio is defined for pattern density range to etch parameter mapping 703 as G1FR3: G2FR3. In some embodiments, the highest pattern density range (PD3-PD4) corresponds to a ratio of not less than 8:1 with a third gas flow rate of the first gas G1FR3 of about 160 SCCM and a third gas flow rate of the second gas G2FR3 of about 20 SCCM. However, other flow rates may be used. In some embodiments, the highest pattern density range (PD3-PD4) corresponds to a ratio of not less than 7.5:1. In some embodiments, the highest pattern density range (PD3-PD4) corresponds to a ratio in the range of 7.5:1 to 9:1.

Such pattern density range and corresponding etchant gas flow ratios may be selected in any manner such that the etchant gas flow ratios increase with increasing pattern density. In some embodiments, the increase is monotonic such that the etchant gas flow ratio does not decrease between any change in pattern density. In some embodiments, the first etchant gas ratio is not less than 25% greater than the second etchant gas ratio in response to the first pattern density being not more than 50% greater than the second pattern density. In some embodiments, the first etchant gas ratio is not less than 30% greater than the second etchant gas ratio in response to the first pattern density being not more than 75% greater than the second pattern density.

Turning now to FIG. 7B, in some embodiments, a total gas flow of the second etchant gas may be split between a center region of the workpiece and an edge region of the workpiece for improved edge effects of the etch.

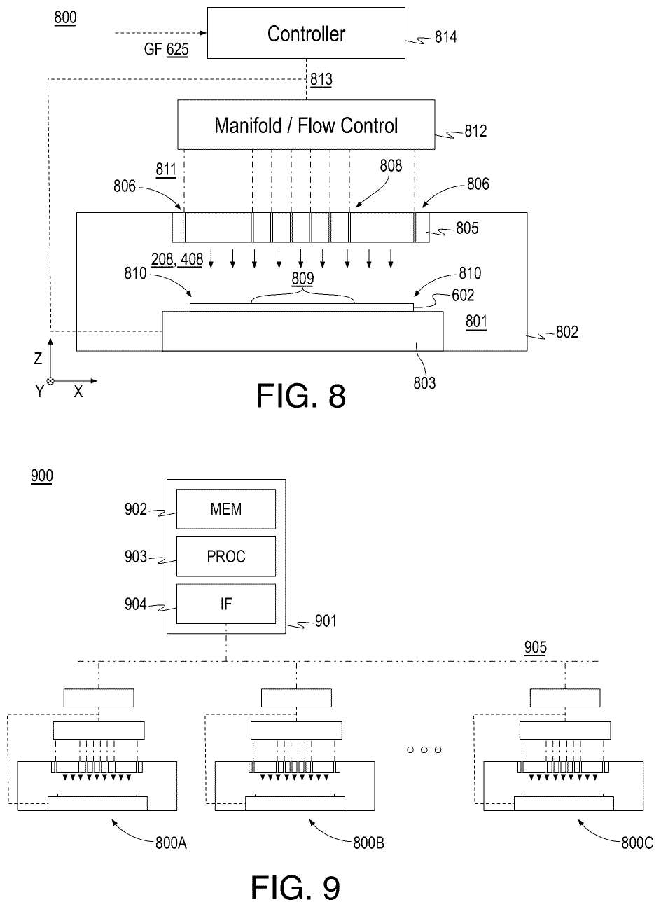

FIG. 8 is an illustration of an example etch tool 800 for fabricating integrated circuit devices using automatically selected etch parameters based on pattern density, arranged in accordance with at least some implementations of the present disclosure. For example, system 600 may implement process 100 and/or other operations discussed herein. In some embodiments, etch tool 800 is deployed as etch tool 618 of system 600 (refer to FIG. 6).

As shown, etch tool 800 includes a process controller 814 for receiving etchant gas ratios or gas flows (GF) 625 and controlling etch tool 800, via control signals 813 to a manifold and/or flow controller 812, to provide the gas flows to a process chamber 801. Etch tool 800 further includes a substrate support 803 (e.g., a chuck) to hold patterned workpiece 602 (i.e., to form etched workpiece 603, a housing 802 that encloses process chamber 801, and a spray head 805 having central nozzles 808 and edge nozzles 806. Central nozzles 808 and edge nozzles 806 are coupled to manifold and/or flow controller 812 by etchant gas supply lines 811. Manifold and/or flow controller 812 controls the flows of the etchant gases from etchant gas supply lines 811 to process chamber 801 in accordance with the discussed etchant gas ratios.

In some embodiments, etch tool 800 includes process chamber 801 fluidly coupled to etchant gas supply lines 811. For example, process chamber 801 may be fluidly coupled to etchant gas supply lines 811 through central nozzles 808 and edge nozzles 806 of spray head 805. In some embodiments, etch tool 800 includes manifold and/or flow controller 812 coupled to etchant gas supply lines 811 to control etchant gas flow. Manifold and/or flow controller 812 may include any suitable piping, structures, and devices to control the etchant gas flow such as valves, flow controllers, and the like. Etch tool further includes process controller 814, which may include a memory and processor circuitry to perform any operations discussed herein. In some embodiments, process controller 814 is implemented as etch tool station controller 617 etch tool station controller 617

As shown with respect to etch tool 800, in some embodiments, the flow rate of etchant gas to a central region 809 (or center) of a material layer on patterned workpiece 602 may be controlled separately relative to the flow rate of etchant gas proximal to an edge region 810 (or edge) of the material layer. In some embodiments, a total flow of the etchant gases is provided in accordance with the etchant ratios discussed herein such that the ratio is substantially the same in central region 809 and edge region 810. In other embodiments, the ratio is controlled to be different in central region 809 relative to that of edge region 810. In some embodiments, etching features into a material layer includes flowing a first gas and a second gas over a center of the material layer, and only the second gas, absent the first gas, proximal to an edge of the material layer. In other embodiments, etching features into a material layer includes flowing a first gas and a second gas over a center of the material layer at a first ratio, and flowing the first gas and the second gas at a second ratio proximal to the edge of the material layer.

Returning to FIG. 7B, as discussed, in some embodiments, a total gas flow of the second etchant gas may be split between a center region of the workpiece and an edge region of the workpiece as provided by, for example, etch tool 800. As shown in FIG. 7B, pattern density to etch parameter mapping 710 includes a number of pattern density range to etch parameter mappings 711, 712, 713 such that a received or determined pattern density 623 can be mapped to corresponding etchant gas ratios or gas flows 625 (refer to FIG. 6) for control of etch processing. As discussed herein, pattern density is defined as the density of openings in the photoresist layer, the density of trenches or holes in the etched material layer, or the density of features embedded in the material layer, all relative to or divided by the total area of the pertinent region.

In the context of etch parameter mapping 710, three ranges of pattern densities (PD) PD1-PD2, PD2-PD3, PD3-PD4 are again used to map pattern densities to etch gas parameters including etch gas flow rate ratios, for example, Pattern densities PD1, PD2, PD3, PD4 may have any values discussed herein with respect to FIG. 7A. In contrast to etch parameter mapping 700, etch parameter mapping 710 includes splitting the total second gas flow rates (G2FR1,T; G2FR2,T; G2FR3,T) into center second gas flow rates (G2FR1,C; G2FR2,C; G2FR3,C) and edge second gas flow rates (G2FR1,E; G2FR2,E; G2FR3,E). The etch gas ratio is then defined with respect to the total second gas flow rates, as shown. The total second gas flow rates and the corresponding etch gas ratios of pattern density range to etch parameter mappings 711, 712, 713 may be any of those discussed with respect to pattern density range to etch parameter mappings 701, 702, 703.

The total second gas flow rates (G2FR1,T; G2FR2,T; G2FR3,T) may be split into any suitable center and edge second gas flow rates. In some embodiments, the edge second gas flow rates (G2FR1,E; G2FR2,E; G2FR3,E) are each about 25% of the total second gas flow rates (G2FR1,T; G2FR2,T; G2FR3,T). In some embodiments, the edge second gas flow rates (G2FR1,E; G2FR2,E; G2FR3,E) are each in the range of 20 to 35% % of the total second gas flow rates (G2FR1,T; G2FR2,T; G2FR3,T). In some embodiments, the edge second gas flow rate of pattern density range to etch parameter mapping 711 (G2FR1,E) is and the edge second gas flow rate of pattern density range to etch parameter mapping 711 (G2FR3,E) are both greater than that of the edge second gas flow rate of pattern density range to etch parameter mapping 712 (G2FR1,E). In some embodiments, G2FR1,E and G2FR3,E are each not less than twice G2FR2,E. In some embodiments, G2FR1,E and G2FR3,E are each not less than four times G2FR2,E.

Turning now to FIG. 7C, in some embodiments, an edge second gas flow for one or more middle pattern density ranges is set to zero as shown with respect to pattern density range to etch parameter mapping 711, as shown with respect to pattern density to etch parameter mapping 720.

For example, pattern density range to etch parameter mapping 721 may have any characteristics discussed with respect to pattern density range to etch parameter mapping 711, and pattern density range to etch parameter mapping 723 may have any characteristics discussed with respect to pattern density range to etch parameter mapping 713. As shown, pattern density range to etch parameter mapping 722 provides no flow of the second gas to the edge of the workpiece. In some embodiments, G1FR1 is in the range of about 100 to 140 SCCM, G1FR2 is in the range of about 100 to 140 SCCM, G1FR3 is in the range of about 140 to 180 SCCM, G2FR1,C is in the range of about 14 to 18 SCCM, G2FR2, C is in the range of about 14 to 18 SCCM, G2FR3,C is in the range of about 14 to 18 SCCM, G2FR1,E is in the range of about 3 to 5 SCCM, G2FR2,E is about 0 SCCM (i.e., not more than 0.1 SCCM), and G2FR3,E is in the range of about 3 to 5SCCM. However, other flow rates may be used.

In pattern density to etch parameter mappings 700, 710, 720, three pattern density ranges are used. However, in some embodiments, additional mappings are used or finer grain or even substantially continuous mapping functions may be use. With reference to FIG. 7D, as shown, pattern density to etch parameter mapping 730 may include any number of pattern density range to etch parameter mappings 731, 732, 733 such that selection may be made from among three etch gas ratios. For example, the etchant gas ratio implemented during etch processing may be selected from a limited number of available etchant gas ratios (G1FR1: G2FR1,T; G1FR2: G2FR2,T; G1FR3: G2FR3,T). In some embodiments, the etchant gas ratios are selected from not fewer than three selectable etchant gas ratios. In some embodiments, the etchant gas ratios are selected from not fewer than four selectable etchant gas ratios. In some embodiments, the etchant gas ratios are selected from not fewer than five or more selectable etchant gas ratios.

Furthermore, the selection of the etchant gas ratios may be made by mapping a pattern density to a pattern density range and look up of the corresponding one of a number of selectable etchant gas ratios in some embodiments. In other embodiments, the selection of the etchant gas ratios may be made by applying a function to the pattern density determine the selected etchant gas ratio. With reference to FIG. 7E, in some embodiments, pattern density to etch parameter mapping 740 includes application of a monotonically increasing function 741 to pattern density 623 to generate an output etchant gas ratio or gas flow 625. Monotonically increasing function 741 may be any suitable function such as a linear function, a step function, a sigmoid function, or the like. In some embodiments, monotonically increasing function 741 applies one of pattern density to etch parameter mappings 700, 710, 720, 730 or pattern densities and etch parameter results similar to those of pattern density to etch parameter mappings 700, 710, 720, 703.

FIG. 9 is an illustration of an example system network 900 of etch tools 800 for fabricating integrated circuit devices using automatically selected etch parameters based on pattern density, arranged in accordance with at least some implementations of the present disclosure. For example, system network 900 may implement any number of etch tools 800A, 800B, 800C, and so on, and one or more controllers 901. As shown, controller 901 includes a memory (MEM) 902, processor circuitry (PROC) 903, and interface circuitry (IF) 904. In some embodiments, interface circuitry 904 is implemented as part of processor circuitry 903.

Memory 902 stores any suitable pattern density data, feature measurement data, gas flow data, etchant gas ratio data, and any other suitable data structure. Processor circuitry 903 accesses memory 902 and manipulates the discussed data structures to translate pattern densities to etchant gas ratios as discussed herein. In some embodiments, controller 901 is connected to a single etch tool 800. In other embodiments, controller 901 is communicatively coupled to any number of etch tools 800A, 800B, 800C such that etchant gas flow data may be provided to any of etch tools 800A, 800B, 800C through network 905. Thereby, a single controller 901 may control any number of etch tools 800A, 800B, 800C in accordance with the disclosed techniques.

Implementing automated process control-based etchant parameter selection as discussed herein can effectively balance, for example, the CxHxFx/O2 ratio according to pattern density. Such techniques ensure quality etch performance and expand the efficiency of pattern density operation range with reduced variability in performance across various products and technology nodes.

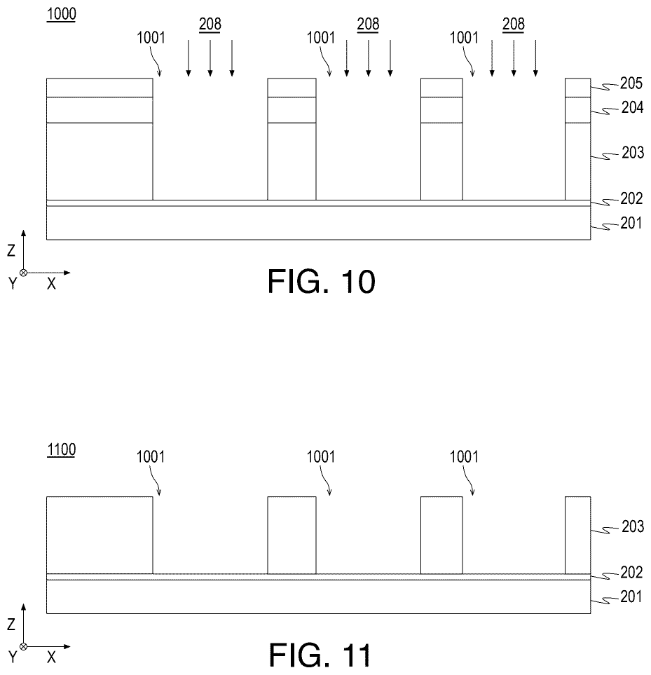

With reference to FIGS. 2, 3, 4, and 5, discussion now turns to continued processing after etching the pattern of patterned photoresist layers 205, 405 into material layers 203, 403. Such processing is illustrated with respect to integrated circuit device structure 200 to fabricate integrated circuit device structures 1000, 1100, and 1200 of FIGS. 10, 11, and 12. The same processing may be provided with respect to integrated circuit device structure 400 to fabricate integrated circuit device structure 1300 of FIG. 13 with the intervening integrated circuit device structures not being shown for the sake of brevity.

FIG. 10 illustrates a cross-sectional side view of an example integrated circuit device structure 1000 having a relatively high pattern density after etch processing, arranged in accordance with at least some implementations of the present disclosure. For example, integrated circuit device structure 1000 is similar to integrated circuit device structure 200 of FIG. 2 after portions 207 of optional sacrificial light absorbing material 204 and material layer 203 are etched using the selected etchant gas ratio of plasma etchant gases 208 to form openings 1001. As shown, openings 1001 extend through sacrificial light absorbing material 204, material layer 203, but not through etch stop layer 202. Openings 1001 may have any shape. For example, openings 1001 may be trenches, holes, or the like that define a shape for a subsequent structure.

FIG. 11 illustrates a cross-sectional side view of an example integrated circuit device structure 1100 having a relatively high pattern density after patterned photoresist layer 205 and sacrificial light absorbing material 204 removal, arranged in accordance with at least some implementations of the present disclosure. For example, integrated circuit device structure 1100 is similar to integrated circuit device structure 1000 of FIG. 10 after removal of patterned photoresist layer 205 and removal of optional sacrificial light absorbing material 204. Patterned photoresist layer 205 and sacrificial light absorbing material 204 may be removed using any suitable technique or techniques. In some embodiments, patterned photoresist layer 205 is removed using ashing techniques and sacrificial light absorbing material 204 is removed using selective etch processing.

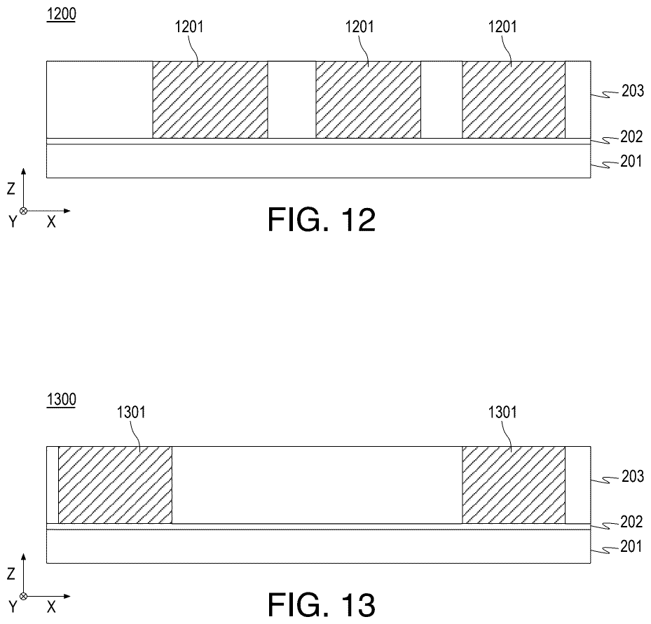

FIG. 12 illustrates a cross-sectional side view of an example integrated circuit device structure 1200 having a relatively high pattern density after formation of metallization structures 1201 embedded in material layer 203, arranged in accordance with at least some implementations of the present disclosure. For example, integrated circuit device structure 1200 is similar to integrated circuit device structure 1100 of FIG. 11 after formation of metallization structures 1201 embedded in material layer 203 such that top surfaces of metallization structures 1201 are coplanar with a top surface of material layer 203. As shown, metallization structures 1201 (and an optional liner, not shown) are formed in a trench of material layer 203. Metallization structures 1201 may be formed using any suitable technique or techniques including electroplating or deposition techniques followed by planarization techniques.

FIG. 13 illustrates a cross-sectional side view of an example integrated circuit device structure 1300 having a relatively low pattern density after etch processing, patterned photoresist layer and sacrificial light absorbing material removal, and formation of metallization structures 1301 embedded in material layer 403, arranged in accordance with at least some implementations of the present disclosure. For example, integrated circuit device structure 1300 is similar to integrated circuit device structure 400 of FIG. 4 after the processing discussed with respect to FIGS. 10-12. As shown, metallization structures 1301 are embedded in material layer 403 such that top surfaces of metallization structures 1301 are coplanar with a top surface material layer 403. Although illustrated with respect to metallization structures 1201, 1301 being formed in trenches, metallization structures 1201, 1301 may be formed in any suitable opening such as contact holes, vias, or the like.

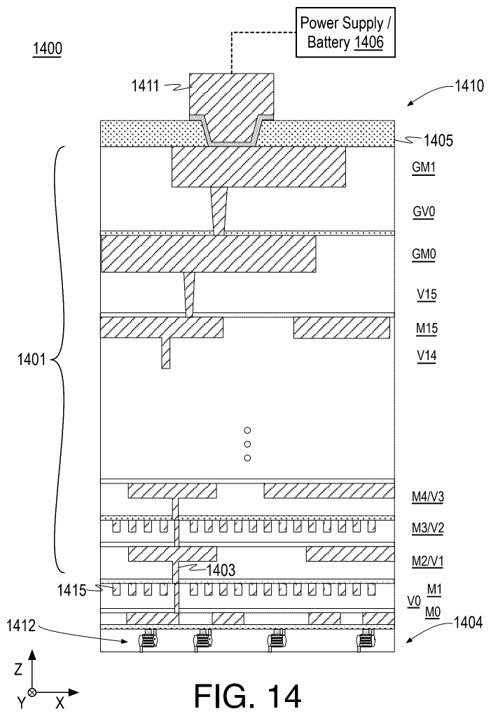

FIG. 14 illustrates a cross-sectional side view of an example integrated circuit device structure 1400 having features formed using automatically selected etch process parameters incorporated in an integrated circuit die 1410, in accordance with at least some embodiments of the present disclosure. As shown, integrated circuit device structure 1400 includes any number of frontside metallization layers 1401 (or frontside interconnect layers). Integrated circuit device structure 1400 may further include backside metallization layers (or backside interconnect layers, not shown), opposite device layer 1404 with respect to frontside metallization layers 1401. Frontside metallization layers 1401 and optional backside metallization layers (not shown) may be formed using any suitable technique or techniques such as dual damascene techniques, single damascene techniques, subtractive metallization patterning techniques, or the like.

For example, interconnectivity, signal routing, power-delivery, and the like may be provided by frontside metallization layers 1401. Adjacent metallization layers, such as metallization interconnects 1415, are interconnected by vias, such as vias 1403, that may be characterized as part of the metallization layers or between the metallization layers. As shown, in some embodiments, frontside metallization layers 1401 are formed over and immediately adjacent a transistor structure 1412. In the illustrated example, frontside metallization layers 1401 include M0, V0, M1, M2/V1, M3/V2, M4/V3, V14, M15, V15, GM0, GV0, and GM1, with metallization layers being labeled M, via layers being labeled V, giant metallization layers being labeled GM, and giant via layers being labeled GV. However, frontside metallization layers 1401 may include any number of metallization layers, via layers, and giant metal layers, and giant via layers.

The techniques for automatically selecting etch process parameters discussed herein may be used to fabricate any layer of integrated circuit device structure 1400 such as any layers of device layer 1404, or any of frontside metallization layers 1401. It is noted that the discussed techniques are particularly advantageous for fabricating GM0, GV0, and GM1 having features with 1080 pitch (i.e., features limited to about 540 nm and spaces optionally being about 540 nm). However, the discussed techniques may be used in the context of any feature sizes

In some embodiments, integrated circuit device structure 1400 is deployed in a monolithic integrated circuit die 1410 including device layer 1404 (e.g., including field effect transistor structure) and frontside metallization layers 1401. As shown, a power supply 1406 may be coupled to integrated circuit die 1410, such that power supply 1406 may include a battery, voltage converter, power supply circuitry, or the like. In some embodiments, power supply 1406 is coupled to integrated circuit die 1410 by interconnects 1411 formed over a passivation layer 1405.

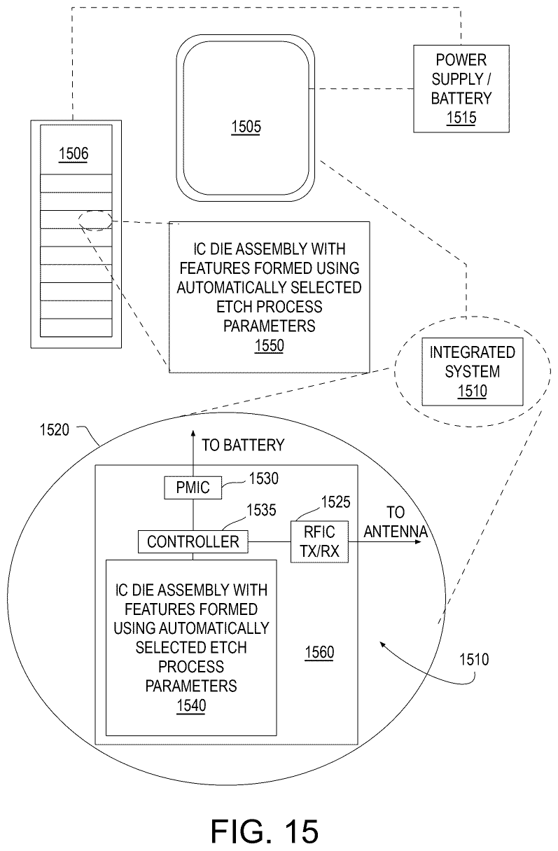

FIG. 15 illustrates exemplary systems employing an integrated circuit assembly including an integrated circuit die having features formed using automatically selected etch process parameters, in accordance with some embodiments. The system may be a mobile computing platform 1505 and/or a data server machine 1506, for example. Either may employ a component assembly including an IC die having features formed using automatically selected etch process parameters as described elsewhere herein. Server machine 1506 may be any commercial server, for example including any number of high-performance computing platforms disposed within a rack and networked together for electronic data processing, which in the exemplary embodiment includes an IC die assembly 1550 with an IC die having features formed using automatically selected etch process parameters as described elsewhere herein. Mobile computing platform 1505 may be any portable device configured for each of electronic data display, electronic data processing, wireless electronic data transmission, or the like. For example, mobile computing platform 1505 may be any of a tablet, a smart phone, a laptop computer, etc., and may include a display screen (e.g., a capacitive, inductive, resistive, or optical touchscreen), a chip-level or package-level integrated system 1510, and a battery 1515. Although illustrated with respect to mobile computing platform 1505, in other examples, chip-level or package-level integrated system 1510 and a battery 1515 may be implemented in a desktop computing platform, an automotive computing platform, an internet of things platform, or the like. As discussed below, in some examples, the disclosed systems may include a sub-system 1560 such as a system on a chip (SOC) or an integrated system of multiple ICs, which is illustrated with respect to mobile computing platform 1505.

Whether disposed within integrated system 1510 illustrated in expanded view 1520 or as a stand-alone packaged device within data server machine 1506, sub-system 1560 may include memory circuitry and/or processor circuitry 1540 (e.g., RAM, a microprocessor, a multi-core microprocessor, graphics processor, etc.), a power management integrated circuit (PMIC) 1530, a controller 1535, and a radio frequency integrated circuit (RFIC) 1525 (e.g., including a wideband RF transmitter and/or receiver (TX/RX)). As shown, one or more IC dies, such as memory circuitry and/or processor circuitry 1540 may be assembled and implemented such that one or more have an IC die having features formed using automatically selected etch process parameters as described herein. In some embodiments, RFIC 1525 includes a digital baseband and an analog front end module further comprising a power amplifier on a transmit path and a low noise amplifier on a receive path). Functionally, PMIC 1530 may perform battery power regulation, DC-to-DC conversion, etc., and so has an input coupled to battery 1515, and an output providing a current supply to other functional modules. As further illustrated in FIG. 15, in the exemplary embodiment, RFIC 1525 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1540 may provide memory functionality for sub-system 1560, high level control, data processing and the like for sub-system 1560. In alternative implementations, each of the SOC modules may be integrated onto separate ICs coupled to a package substrate, interposer, or board.

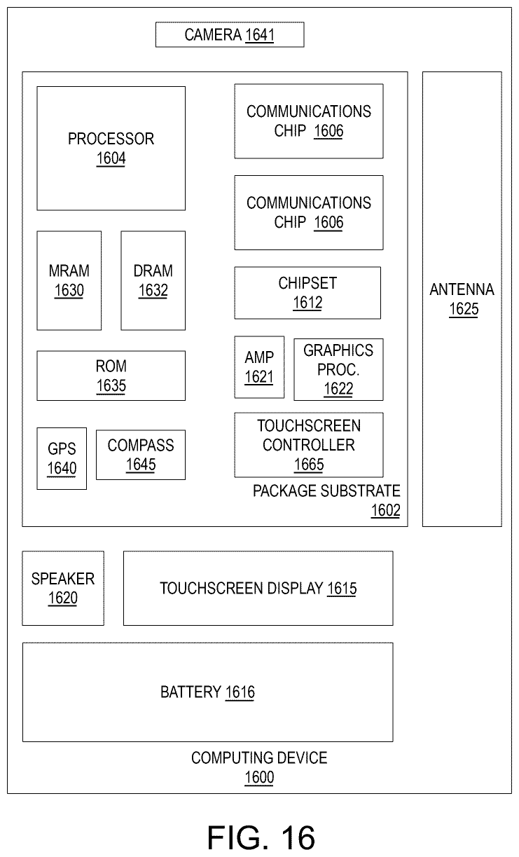

FIG. 16 is a functional block diagram of an electronic computing device 1600, in accordance with some embodiments. For example, device 1600 may, via any suitable component therein, employ an integrated circuit having features formed using automatically selected etch process parameters and/or perform any etch process parameter selection, system control, or other function in accordance with any embodiments described elsewhere herein. Furthermore, any etch process parameter selection, system control, or other function discussed herein may be implemented by representative instructions stored on a machine-readable medium which represents various logic within the processor, which when read by a machine causes the machine to fabricate logic to perform the techniques described herein. Such representations, known as IP cores may be stored on a tangible, machine readable medium and supplied to various customers or manufacturing facilities to load into the fabrication machines that actually make the logic or processor. For example, the machine-readable medium may be included in device 1600.

Device 1600 includes a motherboard or package substrate 1602 hosting a number of components, such as, but not limited to, a processor 1604 (e.g., an applications processor). Processor 1604 may be physically and/or electrically coupled to package substrate 1602. In some examples, processor 1604 is within an IC assembly that includes an IC die having features formed using automatically selected etch process parameters as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 1606 may also be physically and/or electrically coupled to the package substrate 1602. In further implementations, communication chips 1606 may be part of processor 1604. Depending on its applications, computing device 1600 may include other components that may or may not be physically and electrically coupled to package substrate 1602. These other components include, but are not limited to, volatile memory (e.g., DRAM 1632), non-volatile memory (e.g., ROM 1635), flash memory (e.g., NAND or NOR), magnetic memory (MRAM 1630), a graphics processor 1622, a digital signal processor, a crypto processor, a chipset 1612, an antenna 1625, touchscreen display 1615, touchscreen controller 1665, battery 1616, audio codec, video codec, power amplifier 1621, global positioning system (GPS) device 1640, compass 1645, accelerometer, gyroscope, speaker 1620, camera 1641, and mass storage device (such as hard disk drive, solid-state drive (SSD), compact disk (CD), digital versatile disk (DVD), and so forth, or the like.

Communication chips 1606 may enable wireless communications for the transfer of data to and from the computing device 1600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1606 may implement any of a number of wireless standards or protocols, including, but not limited to, those described elsewhere herein. As discussed, computing device 1600 may include a plurality of communication chips 1606. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example the above embodiments may include specific combinations of features as further provided below.

The following pertains to exemplary embodiments.

In one or more first embodiments, a method comprises receiving a first pattern density corresponding to first features to be etched into a first material layer and a second pattern density corresponding to second features to be etched into a second material layer, wherein the first pattern density is greater than the second pattern density and the first material layer and the second material layer comprise substantially the same material composition, selecting a first etchant gas ratio based at least in part on the first pattern density and a second etchant gas ratio based at least in part on the second pattern density, wherein the first etchant gas ratio is greater than the second etchant gas ratio in response to the first pattern density being greater than the second pattern density, and etching the first features into the first material layer using the first etchant gas ratio and the second features into the second material layer using the second etchant gas ratio.

In one or more second embodiments, further to the first embodiments, the first and second etchant gas ratios are ratios of a first gas flow rate to a second gas flow rate, the first gas comprising carbon, hydrogen, and fluorine, and the second gas comprising oxygen, wherein the first and second pattern densities are ratios of a features area within a pattern region to a total area of the pattern region.

In one or more third embodiments, further to the first or second embodiments, the first etchant gas ratio is not less than 25% greater than the second etchant gas ratio in response to the first pattern density being not more than 50% greater than the second pattern density.

In one or more fourth embodiments, further to the first through third embodiments, the first etchant gas ratio is not less than 30% greater than the second etchant gas ratio in response to the first pattern density being not more than 75% greater than the second pattern density.

In one or more fifth embodiments, further to the first through fourth embodiments, etching the second features into the second material layer comprises flowing the first gas and the second gas over a center of the second material layer, and only the second gas, absent the first gas, proximal to an edge of the second material layer, and wherein etching the first features into the first material layer comprises flowing the first gas and the second gas over a center of the first material layer, and flowing no gas proximal to an edge of the first material layer.

In one or more sixth embodiments, further to the first through fifth embodiments, the method further comprises selecting a third etchant gas ratio based at least in part on a third pattern density corresponding to third features to be etched into a third material layer, wherein the third etchant gas ratio is greater than the first etchant gas ratio in response to the third pattern density being greater than the first pattern density, and etching the third features into the third material layer using the third etchant gas ratio, wherein etching the third features into the third material layer comprises flowing the first gas and the second gas over a center of the third material layer, and only the second gas, absent the first gas, proximal to an edge of the third material layer.

In one or more seventh embodiments, further to the first through sixth embodiments, the first etchant gas ratio and the second etchant gas ratio are selected from not fewer than three selectable etchant gas ratios.

In one or more eighth embodiments, further to the first through seventh embodiments, the selectable etchant gas ratios comprise a first selectable etchant gas ratio corresponding to pattern densities of not more than 60%, a second selectable etchant gas ratio corresponding to pattern densities of not more than 70%, and a third etchant gas ratio corresponding to pattern densities of not more than 80%.

In one or more ninth embodiments, further to the first through eighth embodiments, the first etchant gas ratio and the second etchant gas ratio are selected based on a monotonically increasing function of a selected pattern density.

In one or more tenth embodiments, further to the first through ninth embodiments, the first pattern density is based on a design pattern density of the first features and at least one of a measurement of the first features in a photoresist layer over the first material layer or a measurement of the first features etched in a third material layer.

In one or more eleventh embodiments, an apparatus comprises a memory to store a first pattern density corresponding to first features to be etched into a first material layer and a second pattern density corresponding to second features to be etched into a second material layer, wherein the first pattern density is greater than the second pattern density, and processor circuitry coupled to the memory, the processor circuitry to select a first etchant gas ratio based at least in part on the first pattern density and a second etchant gas ratio based at least in part on the second pattern density, wherein the first etchant gas ratio is greater than the second etchant gas ratio in response to the first pattern density being greater than the second pattern density, and transmit the first etchant gas ratio and the second etchant gas ratio to an etch process tool.

In one or more twelfth embodiments, further to the eleventh embodiments, the first and second etchant gas ratios are ratios of a first gas flow rate to a second gas flow rate, the first gas comprising carbon, hydrogen, and fluorine, and the second gas comprising oxygen, wherein the first and second pattern densities are ratios of a features area within a pattern region to a total area of the pattern region.

In one or more thirteenth embodiments, further to the eleventh or twelfth embodiments, the first etchant gas ratio is not less than 25% greater than the second etchant gas ratio in response to the first pattern density being not more than 50% greater than the second pattern density.

In one or more fourteenth embodiments, further to the eleventh through thirteenth embodiments, the first etchant gas ratio and the second etchant gas ratio are selected from not fewer than three selectable etchant gas ratios.

In one or more fifteenth embodiments, further to the eleventh through fourteenth embodiments, the first etchant gas ratio and the second etchant gas ratio are selected based on a monotonically increasing function of a selected pattern density.

In one or more sixteenth embodiments, an apparatus comprises a memory to store a first pattern density corresponding to first features to be etched into a first material layer and a second pattern density corresponding to second features to be etched into a second material layer, wherein the first pattern density is greater than the second pattern density, and processor circuitry coupled to the memory, the processor circuitry to select a first etchant gas ratio based at least in part on the first pattern density and a second etchant gas ratio based at least in part on the second pattern density, wherein the first etchant gas ratio is greater than the second etchant gas ratio in response to the first pattern density being greater than the second pattern density, and transmit the first etchant gas ratio and the second etchant gas ratio to an etch process tool.

In one or more seventeenth embodiments, further to the sixteenth embodiments, the first and second etchant gas ratios are ratios of a first gas flow rate to a second gas flow rate, the first gas comprising carbon, hydrogen, and fluorine, and the second gas comprising oxygen, wherein the first and second pattern densities are ratios of a features area within a pattern region to a total area of the pattern region.

In one or more eighteenth embodiments, further to the sixteenth or seventeenth embodiments, the first etchant gas ratio is not less than 25% greater than the second etchant gas ratio in response to the first pattern density being not more than 50% greater than the second pattern density.

In one or more nineteenth embodiments, further to the sixteenth through eighteenth embodiments, the first etchant gas ratio and the second etchant gas ratio are selected from not fewer than three selectable etchant gas ratios.

In one or more twentieth embodiments, further to the sixteenth through nineteenth embodiments, the first etchant gas ratio and the second etchant gas ratio are selected based on a monotonically increasing function of a selected pattern density.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. A method, comprising:
receiving a first pattern density corresponding to first features to be etched into a first material layer and a second pattern density corresponding to second features to be etched into a second material layer, wherein the first pattern density is greater than the second pattern density and the first material layer and the second material layer comprise substantially the same material composition;
selecting a first etchant gas ratio based at least in part on the first pattern density and a second etchant gas ratio based at least in part on the second pattern density, wherein the first etchant gas ratio is greater than the second etchant gas ratio in response to the first pattern density being greater than the second pattern density; and
etching the first features into the first material layer using the first etchant gas ratio and the second features into the second material layer using the second etchant gas ratio.

2. The method of claim 1, wherein the first and second etchant gas ratios are ratios of a first gas flow rate to a second gas flow rate, the first gas comprising carbon, hydrogen, and fluorine, and the second gas comprising oxygen, wherein the first and second pattern densities are ratios of a features area within a pattern region to a total area of the pattern region.

3. The method of claim 2, wherein the first etchant gas ratio is not less than 25% greater than the second etchant gas ratio in response to the first pattern density being not more than 50% greater than the second pattern density.

4. The method of claim 2, wherein the first etchant gas ratio is not less than 30% greater than the second etchant gas ratio in response to the first pattern density being not more than 75% greater than the second pattern density.

5. The method of claim 2, wherein etching the second features into the second material layer comprises flowing the first gas and the second gas over a center of the second material layer, and only the second gas, absent the first gas, proximal to an edge of the second material layer, and wherein etching the first features into the first material layer comprises flowing the first gas and the second gas over a center of the first material layer, and flowing no gas proximal to an edge of the first material layer.

6. The method of claim 2, further comprising:
selecting a third etchant gas ratio based at least in part on a third pattern density corresponding to third features to be etched into a third material layer, wherein the third etchant gas ratio is greater than the first etchant gas ratio in response to the third pattern density being greater than the first pattern density; and
etching the third features into the third material layer using the third etchant gas ratio, wherein etching the third features into the third material layer comprises flowing the first gas and the second gas over a center of the third material layer, and only the second gas, absent the first gas, proximal to an edge of the third material layer.

7. The method of claim 1, wherein the first etchant gas ratio and the second etchant gas ratio are selected from not fewer than three selectable etchant gas ratios.

8. The method of claim 7, wherein the selectable etchant gas ratios comprise a first selectable etchant gas ratio corresponding to pattern densities of not more than 60%, a second selectable etchant gas ratio corresponding to pattern densities of not more than 70%, and a third etchant gas ratio corresponding to pattern densities of not more than 80%.

9. The method of claim 1, wherein the first etchant gas ratio and the second etchant gas ratio are selected based on a monotonically increasing function of a selected pattern density.

10. The method of claim 1, wherein the first pattern density is based on a design pattern density of the first features and at least one of a measurement of the first features in a photoresist layer over the first material layer or a measurement of the first features etched in a third material layer.

11. An apparatus, comprising:
a process chamber fluidly coupled to one or more etchant gas supply lines;
one or more flow controllers coupled to the coupled to one or more etchant gas supply lines; and
a process controller coupled to the one or more flow controllers, the process controller to:
select a first etchant gas ratio based at least in part on a first pattern density and a second etchant gas ratio based at least in part on a second pattern density, wherein the first etchant gas ratio is greater than the second etchant gas ratio in response to the first pattern density being greater than the second pattern density;
transmit the first etchant gas ratio to the one or more flow controllers to flow a first etchant gas and a second etchant gas, in accordance with the first etchant gas ratio, to the process chamber to etch a first material layer; and
transmit the second etchant gas ratio to the one or more flow controllers to flow the first etchant gas and the second etchant gas, in accordance with the second etchant gas ratio, to the process chamber to etch a second material layer.

12. The apparatus of claim 11, wherein the first and second etchant gas ratios are ratios of a first gas flow rate to a second gas flow rate, the first gas comprising carbon, hydrogen, and fluorine, and the second gas comprising oxygen, wherein the first and second pattern densities are ratios of a features area within a pattern region to a total area of the pattern region.

13. The apparatus of claim 11, wherein the first etchant gas ratio is not less than 25% greater than the second etchant gas ratio in response to the first pattern density being not more than 50% greater than the second pattern density.

14. The apparatus of claim 11, wherein the first etchant gas ratio and the second etchant gas ratio are selected from not fewer than three selectable etchant gas ratios.

15. The apparatus of claim 11, wherein the first etchant gas ratio and the second etchant gas ratio are selected based on a monotonically increasing function of a selected pattern density.

16. An apparatus, comprising:
a memory to store a first pattern density corresponding to first features to be etched into a first material layer and a second pattern density corresponding to second features to be etched into a second material layer, wherein the first pattern density is greater than the second pattern density; and
processor circuitry coupled to the memory, the processor circuitry to:
select a first etchant gas ratio based at least in part on the first pattern density and a second etchant gas ratio based at least in part on the second pattern density, wherein the first etchant gas ratio is greater than the second etchant gas ratio in response to the first pattern density being greater than the second pattern density; and
transmit the first etchant gas ratio and the second etchant gas ratio to an etch process tool.

17. The apparatus of claim 16, wherein the first and second etchant gas ratios are ratios of a first gas flow rate to a second gas flow rate, the first gas comprising carbon, hydrogen, and fluorine, and the second gas comprising oxygen, wherein the first and second pattern densities are ratios of a features area within a pattern region to a total area of the pattern region.

18. The apparatus of claim 16, wherein the first etchant gas ratio is not less than 25% greater than the second etchant gas ratio in response to the first pattern density being not more than 50% greater than the second pattern density.

19. The apparatus of claim 16, wherein the first etchant gas ratio and the second etchant gas ratio are selected from not fewer than three selectable etchant gas ratios.

20. The apparatus of claim 16, wherein the first etchant gas ratio and the second etchant gas ratio are selected based on a monotonically increasing function of a selected pattern density.
